(19) United States
(12) Patent Application Publication
(10) Pub. No.: US 2024/0222337 A1
(43) Pub. Date: Jul. 4, 2024

(54) DISPLAY DEVICE WITH REPAIRABLE SUB PIXELS

(71) Applicant: LG DISPLAY CO., LTD., Seoul (KR)

(72) Inventors: MinSeok Kim, Seoul (KR); Hun Jang, Paju-si (KR)

(73) Assignee: LG DISPLAY CO., LTD., SEOUL (KR)

(21) Appl. No.: 18/217,112

(22) Filed: Jun. 30, 2023

(30) Foreign Application Priority Data
Dec. 29, 2022 (KR) 10-2022-0189037

(51) Int. Cl. H01L 25/075; H01L 33/38; H01L 33/62

(52) U.S. Cl. CPC H01L 25/0753; H01L 33/382; H01L 33/62

(57) ABSTRACT

According to an aspect of the present disclosure, a display device includes a substrate on which a pixel including a plurality of sub pixels is disposed; a bonding layer on the substrate; a plurality of light-emitting elements in a first subset of the plurality of sub pixels and disposed on the bonding layer; a planarization layer on the bonding layer and the plurality of light-emitting elements; and an additional light-emitting element in a second subset of the plurality of sub pixels and disposed on the planarization layer.

### CROSS-REFERENCE TO RELATED APPLICATIONS

This application claims the priority of Korean Patent Application No. 10-2022-0189037 filed on Dec. 29, 2022, in the Korean Intellectual Property Office, the disclosure of which is incorporated herein by reference.

### BACKGROUND

### Field of the Disclosure

The present specification relates to a display device, and more particularly, to a display device using a light-emitting diode (LED).

### Description of the Background

Display devices are used for a wide range of applications including being used as a monitor of a computer, a TV set, a mobile phone, and the like. Display devices can include an organic light-emitting display (OLED) configured to autonomously emit light, a liquid crystal display (LCD) that requires a separate light source, etc.

Research and development in this space are partially focused on development of display devices having wide display areas and/or reduced volumes and weights.

Recently, display devices having light-emitting diodes (LED) have garnered interest and attention as a next-generation display device. Because an LED is made of an inorganic material instead of an organic material, the LED device is more reliable and has a longer lifespan than a liquid crystal display device or an organic light-emitting display device. In addition, the LED can be quickly turned on or off, have excellent luminous efficiency, high impact resistance, and great stability, and display high-brightness images.

### SUMMARY

One or more aspects of the present disclosure are directed to display devices in which a sub pixel having a transfer defect of a light-emitting element is repaired.

In one aspect, a display device includes a substrate on which a pixel including a plurality of sub pixels is disposed; a bonding layer on the substrate; a plurality of light-emitting elements in a first subset of the plurality of sub pixels and disposed on the bonding layer; a planarization layer on the bonding layer and the plurality of light-emitting elements; and an additional light-emitting element in a second subset of the plurality of sub pixels and disposed on the planarization layer

In another aspect, the plurality of light-emitting elements each includes a first semiconductor layer on the bonding layer; a second semiconductor layer on the first semiconductor layer; a light-emitting layer between the first semiconductor layer and the second semiconductor layer; a first electrode on the first semiconductor layer; and a second electrode on the second semiconductor layer.

In another aspect, the additional light-emitting element includes a first additional semiconductor layer; a second additional semiconductor layer below the first additional semiconductor layer; an additional light-emitting layer between the first additional semiconductor layer and the second additional semiconductor layer; a first additional electrode disposed below the first additional semiconductor layer; and a second additional electrode disposed below the second additional semiconductor layer.

In another aspect, the display device further includes a first connection electrode provided in each of the plurality of sub pixels and disposed on the planarization layer; and a second connection electrode provided in each of the plurality of sub pixels, disposed on the planarization layer, and spaced apart from the first connection electrode. The first connection electrode is electrically connected to the first electrode and the first additional electrode, and the second connection electrode is electrically connected to the second electrode and the second additional electrode.

In another aspect, the planarization layer further includes a groove that overlaps the first additional electrode and the second additional electrode in the sub pixel on which the additional light-emitting element is disposed among the plurality of sub pixels, and the first connection electrode and the second connection electrode are formed in a concave shape along the groove.

In another aspect, the display device further includes a first bonding electrode provided in the groove and disposed between the first connection electrode and the first additional electrode; and a second bonding electrode provided in the groove and disposed between the second connection electrode and the second additional electrode.

In another aspect, an upper portion of the first bonding electrode and an upper portion of the second bonding electrode are disposed on an upper portion of the first connection electrode and an upper portion of the second connection electrode, and the upper portion of the first bonding electrode and the upper portion of the second bonding electrode each have an inversely tapered shape.

In another aspect, the first connection electrode and the second connection electrode are each made of a transparent conductive material, and the first bonding electrode and the second bonding electrode are each made of an opaque conductive material.

In another aspect, the plurality of light-emitting elements is disposed in the sub pixel different from the sub pixel on which the first bonding electrode and the second bonding electrode are disposed.

In another aspect, the plurality of sub pixels comprises a plurality of first sub pixels, a plurality of second sub pixels, a plurality of third sub pixels, and one or more defective sub pixels, the first subset of the plurality of subpixels in which the plurality of light-emitting elements is disposed includes the plurality of first sub pixels, the plurality of second sub pixels, and the plurality of third sub pixels, and the second subset of the plurality of subpixels in which the additional light-emitting element is disposed includes the one or more defective sub pixels.

In another aspect, the first bonding electrode and the second bonding electrode are disposed in the one or more defective sub pixels.

In another aspect, the plurality of sub pixels comprises a plurality of first sub pixels, a plurality of second sub pixels, a plurality of third sub pixels, and a plurality of repair sub pixels, the first subset of the plurality of subpixels in which the plurality of light-emitting elements is disposed includes the plurality of first sub pixels, the plurality of second sub pixels, and the plurality of third sub pixels, and the second subset of the plurality of subpixels in which the additional light-emitting element is disposed includes one of the plurality of repair sub pixels.

In another aspect, the first bonding electrode and the second bonding electrode are disposed in the plurality of repair sub pixels.

In one aspect, a display device includes a plurality of sub pixels formed on a substrate; a bonding layer on the substrate; a plurality of light-emitting elements formed on the bonding layer; a planarization layer on the bonding layer and the plurality of light-emitting elements; and at least one additional light-emitting element formed on the planarization layer.

In another aspect, the plurality of light-emitting elements and the at least one additional light-emitting element are formed in different subsets of the plurality of sub pixels.

In another aspect, the plurality of sub pixels includes a plurality of first sub pixels, a plurality of second sub pixels, a plurality of third sub pixels, and one or more defective sub pixels, the plurality of light-emitting elements is formed in the plurality of first sub pixels, the plurality of second sub pixels, and the plurality of third sub pixels, and the additional light-emitting element is formed in the one or more defective sub pixels.

In another aspect, the plurality of sub pixels includes a plurality of first sub pixels, a plurality of second sub pixels, a plurality of third sub pixels, and a plurality of repair sub pixels, the plurality of light-emitting elements is formed in the plurality of first sub pixels, the plurality of second sub pixels, and the plurality of third sub pixels, and the additional light-emitting element is formed in one of the plurality of repair sub pixels.

In another aspect, the plurality of light-emitting elements each includes a first semiconductor layer on the bonding layer; a second semiconductor layer on the first semiconductor layer; a light-emitting layer between the first semiconductor layer and the second semiconductor layer; a first electrode on the first semiconductor layer; and a second electrode on the second semiconductor layer.

In another aspect, the additional light-emitting element includes a first additional semiconductor layer; a second additional semiconductor layer below the first additional semiconductor layer; an additional light-emitting layer between the first additional semiconductor layer and the second additional semiconductor layer; a first additional electrode disposed below the first additional semiconductor layer; and a second additional electrode disposed below the second additional semiconductor layer.

In another aspect, the display device further includes a bank layer formed of an opaque material on the planarization layer

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an exemplary aspect of the present specification;

FIG. 2A is a partial cross-sectional view of the display device according to an exemplary aspect of the present specification;

FIG. 2B is a perspective view of a tiling display device according to an exemplary aspect of the present specification;

FIG. 3A is a schematic enlarged top plan view of the display device according to an exemplary aspect of the present specification;

FIG. 3B is a schematic top plan view of the display device according to an exemplary aspect of the present specification;

FIG. 4 is a cross-sectional view of a first sub pixel of the display device according to an exemplary aspect of the present specification;

FIG. 5 is an enlarged top plan view of the display device according to an exemplary aspect of the present specification;

FIG. 6 is a cross-sectional view of a defective sub pixel of the display device according to an exemplary aspect of the present specification;

FIGS. 7A to 7D are process diagrams for explaining a method of manufacturing the display device according to an exemplary aspect of the present specification;

FIG. 8 is a schematic enlarged top plan view of a display device according to an exemplary aspect of the present specification; and

FIG. 9 is a cross-sectional view of a repair sub pixel of the display device according to an exemplary aspect of the present specification.

### DETAILED DESCRIPTION

Various examples of the present disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be directly disposed on the another layer or another element, or other element or layer may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely adhered to or combined with each other and may be interlocked and operated in technically various ways, and the embodiments may be carried out independently of or in association with each other.

Hereinafter, a display device according to exemplary embodiments of the present disclosure will be described in detail with reference to accompanying drawings.

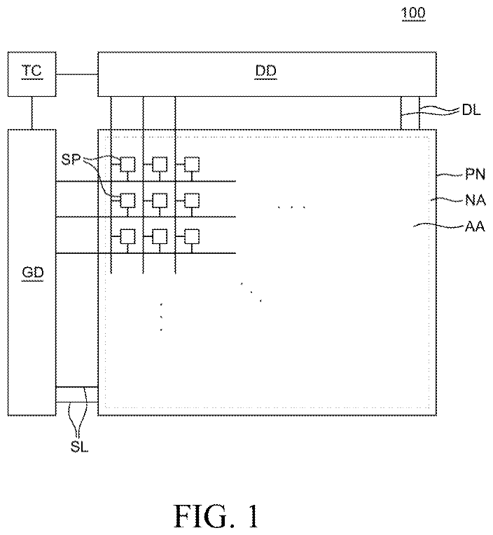

FIG. 1 is a schematic configuration view of a display device according to an exemplary aspect of the present specification. For convenience of description, FIG. 1 illustrates only a display panel PN, a gate driver GD, a data driver DD, and a timing controller TC among various constituent elements of a display device 100. However, a display device of the present disclosure and its components are not limited to those shown in FIG. 1 and display device 100 can include any other known or to be developed component.

With reference to FIG. 1, the display device 100 includes the display panel PN including a plurality of sub pixels SP, the gate driver GD and the data driver DD configured to supply various types of signals to the display panel PN, and the timing controller TC configured to control the gate driver GD and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number of and arrangement of the gate driver GD are not limited thereto.

The data driver DD converts image data, which are inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which are inputted from the outside, and supplies the image data to the data driver DD. The timing controller TC may generate the gate control signals and the data control signals by using synchronizing signals, for example, dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images for viewing and includes the plurality of sub pixels SP. In the display panel PN, the plurality of scan lines SL, and the plurality of data lines DL intersect one another, and each of the plurality of sub pixels SP is connected to the scan line SL and the data line DL. In addition, although not illustrated in the drawings, the plurality of sub pixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of sub pixels SP constituting a plurality of pixels PX, and a circuit configured to operate the plurality of sub pixels SP. The plurality of sub pixels SP is minimum units that constitute the display area AA. The n sub pixels SP may constitute a single pixel PX. A light-emitting element, a thin-film transistor for operating the light-emitting element, and the like may be disposed in each of the plurality of sub pixels SP. The plurality of light emitting elements may have different configurations depending on the type of display panel PN. For example, in case that the display panel PN is an inorganic light-emitting display panel, the light-emitting element may be a light-emitting diode (LED) or a micro light-emitting diode (micro LED).

A plurality of signal lines for transmitting various types of signals to the plurality of sub pixels SP is disposed in the display area AA. For example, the plurality of signal lines may include the plurality of data lines DL for supplying data voltages to the plurality of sub pixels SP, and the plurality of scan lines SL for supplying gate voltages to the plurality of sub pixels SP. The plurality of scan lines SL may extend in one direction in the display area AA and be connected to the plurality of sub pixels SP. The plurality of data lines DL may extend in a direction different from one direction in the display area AA and be connected to the plurality of sub pixels SP. In addition, the low-potential power line, the high-potential power line, and the like may be further disposed in the display area AA. However, the present disclosure is not limited thereto.

The non-display area NA may be defined as an area in which no image is displayed, i.e., an area extending from the display area AA to the edges of the display panel PN. The non-display area NA may include link lines and pad electrodes for transmitting signals to the sub pixels SP in the display area AA. Alternatively, the non-display area NA may include drive ICs such as gate drivers IC and data drivers IC.

The non-display area NA may be positioned on a rear surface of the display panel PN, i.e., a surface on which the sub pixel SP is not present. Alternatively, the non-display area NA may be excluded. However, the present disclosure is not limited to the configuration illustrated in the drawings.

The drivers such as the gate driver GD, the data driver DD, and the timing controller TC may be connected to the display panel PN in various ways. For example, the gate driver GD may be mounted in the non-display area NA by a gate-in-panel (GIP) method or mounted between the plurality of sub pixels SP by a gate-in-active area (GIA) method in the display area AA. In one example, the data driver DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, it is necessary to ensure an area of the non-display area NA the gate driver GD and the pad electrode may be disposed in an area of the non-display area NA. This area may increase a bezel.

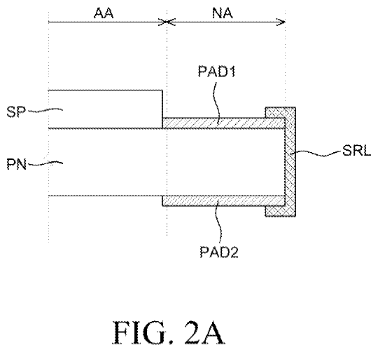

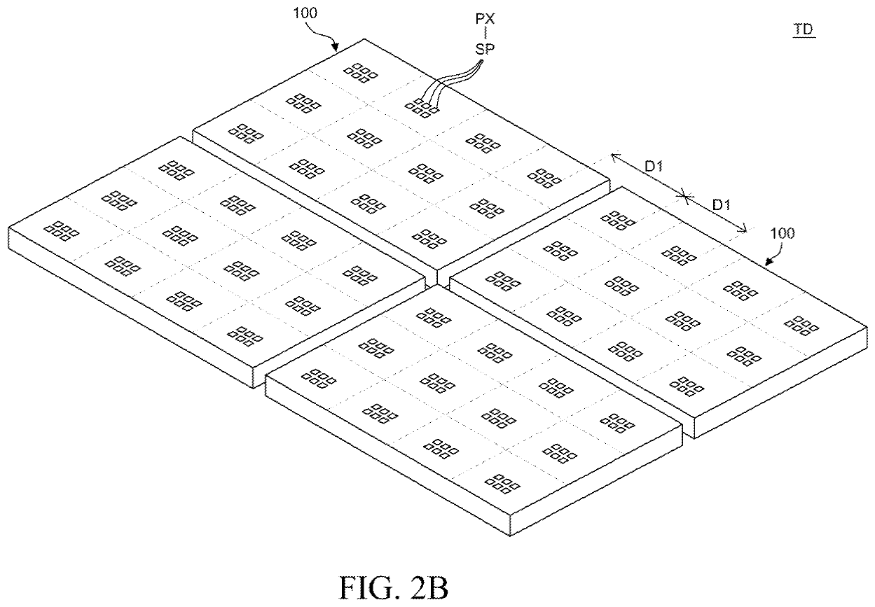

Alternatively, in case that the gate driver GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented. A more detailed description will be made with reference to FIGS. 2A and 2B.

FIG. 2A is a partial cross-sectional view of the display device according to the exemplary aspect of the present specification. FIG. 2B is a perspective view of a tiling display device according to the exemplary aspect of the present specification.

A plurality of pad electrodes for transmitting various types of signals to the plurality of sub pixels SP is disposed in the non-display area NA of the display panel PN. For example, a first pad electrode PAD1 configured to transmit signals to the plurality of sub pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub pixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub pixels SP through the second pad electrode PAD2, the side line SRL, and the first pad electrode PAD1. Therefore, a signal transmission route is defined from the front surface to the side surface and the rear surface of the display panel PN, which minimizes an area of the non-display area NA of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the minimized bezel, a blank area in which no image is displayed between the display devices 100 may be minimized, thereby improving display quality.

For example, the plurality of sub pixels SP may constitute a single pixel PX. An interval D1 between an outermost peripheral pixel PX of one display device 100 and an outermost peripheral pixel PX of another display device 100 adjacent to one display device 100 may be implemented to be equal to the interval D1 between the pixels PX in one display device 100. Therefore, the blank area may be minimized as a constant interval of the pixels PX is implemented between the one display device 100 and the another display device 100.

FIG. 2A and FIG. 2B are illustrative, the display device 100 according to the exemplary aspect of the present specification may be a general display device 100 in which the bezel is present. However, the present disclosure is not limited thereto.

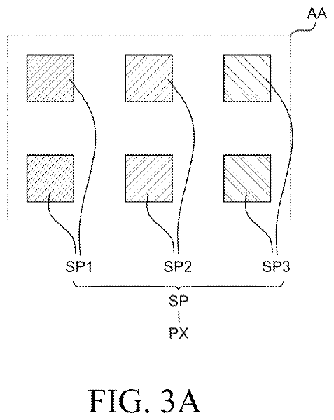

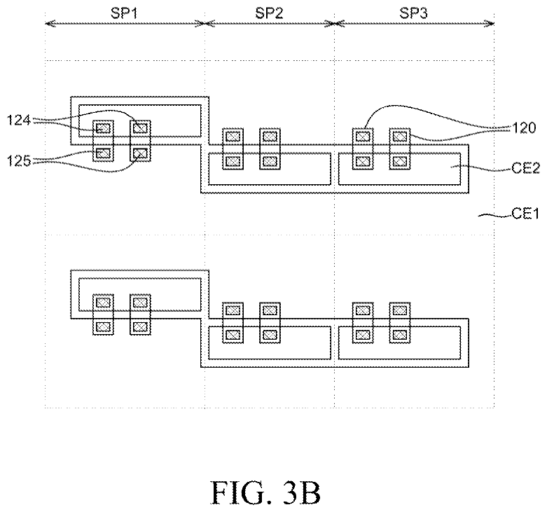

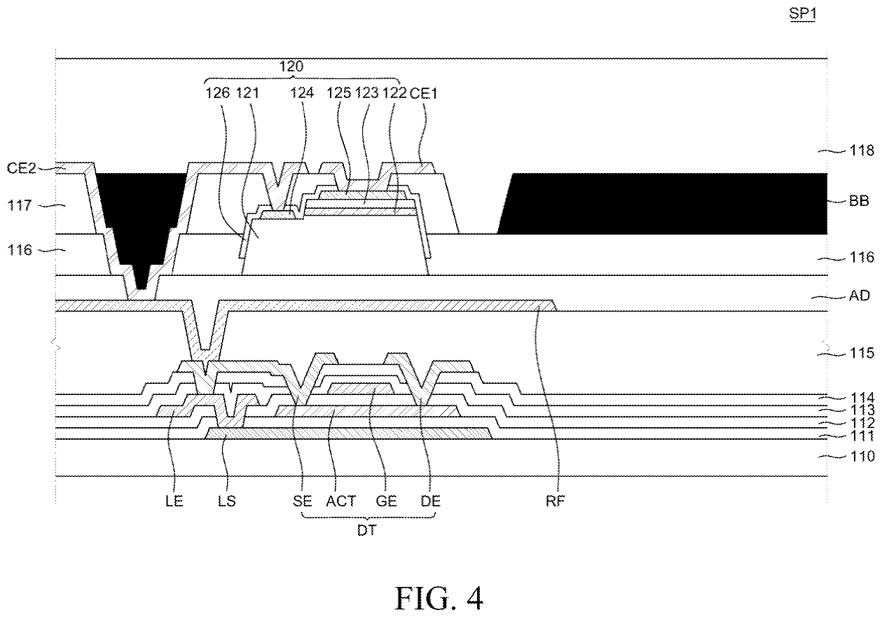

FIG. 3A is a schematic enlarged top plan view of the display device according to the exemplary aspect of the present specification. FIG. 3B is a schematic top plan view of the display device according to the exemplary aspect of the present specification. FIG. 4 is a cross-sectional view of a first sub pixel of the display device according to the exemplary aspect of the present specification.

With reference to FIGS. 3A and 3B, the display panel PN includes the plurality of pixels PX each having the plurality of sub pixels SP. The plurality of sub pixels SP may each include a light-emitting element 120 and a pixel circuit and independently emit light. The single pixel PX may include one or more first sub pixels SP1, one or more second sub pixels SP2, and one or more third sub pixels SP3. For example, the single pixel PX may include two first sub pixels SP1, two second sub pixels SP2, and two third sub pixels SP3. In this case, the first sub pixel SP1 may be a red sub pixel, the second sub pixel SP2 may be a green sub pixel, and the third sub pixel SP3 may be a blue sub pixel. However, the present disclosure is not limited thereto.

Next, with reference to FIG. 4, a substrate 110, a buffer layer 111, a gate insulation layer 112, a first interlayer insulation layer 113, a second interlayer insulation layer 114, a first planarization layer 115, a bonding layer AD, a second planarization layer 116, a third planarization layer 117, a bank BB, a driving transistor DT, the light-emitting element 120, a reflective layer RF, a plurality of first connection electrodes CE1, a second connection electrode CE2, a light-blocking layer LS, and an auxiliary electrode LE are disposed in the plurality of sub pixels SP of the display panel PN of the display device 100 according to the exemplary aspect of the present specification.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS is disposed on the substrate 110 in each of the plurality of sub pixels SP. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). The buffer layer 111 may be excluded in accordance with the type of substrate 110 or the type of transistor. However, the present disclosure is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulation layer 112 is disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present disclosure is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 and the second interlayer insulation layer 114 are disposed on the gate electrode GE. Contact holes, through which the source electrode SE and the drain electrode DE are connected to the active layer ACT are formed in the first interlayer insulation layer 113 and the second interlayer insulation layer 114. The first interlayer insulation layer 113 and the second interlayer insulation layer 114 may be insulation layers for protecting a lower portion of the source electrode SE and a lower portion of the drain electrode DE and each configured as a single layer or multilayer made of silicon oxide (SiOx) or silicon nitride (SiNx). However, the present disclosure is not limited thereto.

The source electrode SE and the drain electrode DE are disposed on the second interlayer insulation layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In the present specification, example configurations have been described in which the first interlayer insulation layer 113 and the second interlayer insulation layer 114, i.e., the plurality of insulation layers, is disposed between the gate electrode GE and the source electrode SE, and the drain electrode DE. In another example, only a single insulation layer may be disposed between the gate electrode GE and the source electrode SE, and the drain electrode DE. However, the present disclosure is not limited to these configurations.

Further, as illustrated in the drawings, in case that the plurality of insulation layers, such as the first interlayer insulation layer 113 and the second interlayer insulation layer 114, is disposed between the gate electrode GE and the source electrode SE, and the drain electrode DE, an electrode may be additionally formed between the first interlayer insulation layer 113 and the second interlayer insulation layer 114. The additionally formed electrode may define a capacitor together with other components disposed on the lower portion of the first interlayer insulation layer 113 or the upper portion of the second interlayer insulation layer 114.

The auxiliary electrode LE is disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the source electrode SE. In another example, the light-blocking layer LS may be connected to the drain electrode DE. However, the present disclosure is not limited thereto.

The first planarization layer 115 is disposed on the driving transistor DT. The first planarization layer 115 may planarize the upper portion of the substrate 110 on which the driving transistor DT is disposed. The first planarization layer 115 may be configured as a single layer or multilayer and made of a photoresist or an acrylic-based organic material, for example. However, the present disclosure is not limited thereto.

The reflective layer RF may be disposed on the first planarization layer 115. The reflective layer RF may reflect light, which is emitted from the light-emitting element 120, toward an upper portion of the light-emitting element 120, thereby improving luminous efficiency of the display device 100. The reflective layer RF may be made of an electrically conductive material having excellent reflection performance and reflect the light, which is emitted from the light-emitting element 120, toward the upper portion of the light-emitting element 120. Further, the reflective layer RF may serve as a reflective plate and also serve as an electrode that electrically connects the light-emitting element 120 to the driving transistor DT.

The bonding layer AD is disposed on the reflective layer RF. The front surface of the substrate 110 may be coated with the bonding layer AD, and the bonding layer AD may fix the light-emitting element 120 disposed on the bonding layer AD. For example, the bonding layer AD may be made of any one material selected from adhesive polymer, epoxy resist, UV resin, a polyimide-based material, an acrylate-based material, an urethane-based material, and polydimethylsiloxane (PDMS). However, the present disclosure is not limited thereto.

The plurality of light-emitting elements 120 is provided on the bonding layer AD and disposed in each of the plurality of sub pixels SP. The plurality of light-emitting elements 120 may be elements configured to emit light by using an electric current and include the light-emitting elements 120 configured to emit red light, green light, blue light, and the like. The plurality of light-emitting elements 120 may implement light with various colors including white by using a combination of red light, green light, blue light, and the like. For example, the plurality of light-emitting elements 120 may each be a light-emitting diode (LED) or a micro LED. However, the present disclosure is not limited thereto.

The light-emitting element 120 includes a first semiconductor layer 121, a light-emitting layer 122, a second semiconductor layer 123, a first electrode 124, a second electrode 125, and a passivation layer 126.

The first semiconductor layer 121 is disposed on the bonding layer AD, and the second semiconductor layer 123 is disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 may emit light by receiving holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 is disposed on the first semiconductor layer 121. The first electrode 124 is an electrode that electrically connects a power line and the first semiconductor layer 121. The first electrode 124 may be disposed on a top surface of the first semiconductor layer 121 exposed from the light-emitting layer 122 and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 may be disposed on a top surface of the second semiconductor layer 123. The second electrode 125 is an electrode electrically connecting the driving transistor DT and the second semiconductor layer 123. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the passivation layer 126 is disposed to surround the first semiconductor layer 121, the light-emitting layer 122, the second semiconductor layer 123, the first electrode 124, and the second electrode 125. The passivation layer 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the passivation layer 126, such that the first connection electrode CE1, the second connection electrode CE2, the first electrode 124, and the second electrode 125 may be electrically connected.

A part of a side surface of the first semiconductor layer 121 may be exposed from the passivation layer 126. The light-emitting element 120 manufactured on a wafer may be separated from the wafer and transferred to the display panel PN. A part of the passivation layer 126 may be torn during a process of separating the light-emitting element 120 from the wafer. For example, a part of the passivation layer 126 adjacent to a lower edge of the first semiconductor layer 121 of the light-emitting element 120 may be torn during the process of separating the light-emitting element 120 from the wafer, such that a lower portion of the side surface of the first semiconductor layer 121 may be exposed to the outside. In some examples, even though the lower portion of the light-emitting element 120 is exposed from the passivation layer 126, the first connection electrode CE1 and the second connection electrode CE2 are formed after the second and third planarization layers 116 and 117, which cover the side surface of the first semiconductor layer 121, are formed, thereby minimizing a short circuit defect.

The second planarization layer 116 and the third planarization layer 117 are disposed on the bonding layer AD and the light-emitting element 120. The second planarization layer 116 may partially overlap the side surfaces of the plurality of light-emitting elements 120 and fix and protect the plurality of light-emitting elements 120. The third planarization layer 117 may be formed to cover an upper portion of the second planarization layer 116 and an upper portion of the light-emitting element 120. A contact hole, through which the first electrode 124 and the second electrode 125 of the light-emitting element 120 are exposed, may be formed in the third planarization layer 117. The first electrode 124 and the second electrode 125 of the light-emitting element 120 may be exposed from the third planarization layer 117, and the third planarization layer 117 is partially disposed in an area between the first electrode 124 and the second electrode 125, thereby minimizing a short circuit defect. The second planarization layer 116 and the third planarization layer 117 may each be configured as a single layer or multilayer and made of a photoresist or an acrylic-based organic material, for example. However, the present disclosure is not limited thereto. In example embodiments of the present specification, configurations have been described in which the second planarization layer 116 and the third planarization layer 117 are disposed. In another example, the planarization layer may be configured as a single layer. However, the present disclosure is not limited thereto.

In another example, the third planarization layer 117 may cover only an area adjacent to the light-emitting element 120. The third planarization layer 117 may be formed only in an area in which the bank BB is not formed. The third planarization layer 117 may be disposed in an area of the sub pixel SP surrounded by the bank BB and disposed in the form of an island. Therefore, the bank BB may be disposed on a part of a top surface of the second planarization layer 116, and the third planarization layer 117 may be disposed on another part of the top surface of the second planarization layer 116.

The first connection electrode CE1 and the second connection electrode CE2 are disposed on the third planarization layer 117. The first connection electrode CE1 is an electrode that electrically connects the power line and the second electrode 125 of the light-emitting element 120. The first connection electrode CE1 may be electrically connected to the second electrode 125 of the light-emitting element 120 through the contact hole formed in the third planarization layer 117.

The second connection electrode CE2 is an electrode that electrically connects the driving transistor DT and the first electrode 124 of the light-emitting element 120. The second connection electrode CE2 may be connected to the reflective layer RF of each of the plurality of sub pixels SP through the contact holes formed in the third planarization layer 117, the second planarization layer 116, and the bonding layer AD. In this case, because the reflective layer RF is also connected to the driving transistor DT, the driving transistor DT and the first electrode 124 of the light-emitting element 120 may be electrically connected through the reflective layer RF and the second connection electrode CE2.

The first connection electrode CE1 and the second connection electrode CE2 may each be made of a transparent electrically conductive material, for example, indium tin oxide (ITO), indium zinc oxide (IZO), or the like. The first and second connection electrodes CE1 and CE2, which cover the light-emitting element 120, are made of transparent materials, such that light emitted from the light-emitting element 120 may propagate to the outside of the display device 100.

The bank BB is disposed on the second planarization layer 116 exposed from the third planarization layer 117. The bank BB may be disposed to be spaced apart from the third planarization layer 117 and the light-emitting element 120 at a predetermined interval. The bank BB may be made of an opaque material, for example, black resin to reduce a color mixture between the plurality of sub pixels SP. However, the present disclosure is not limited thereto.

A protective layer 118 is disposed on the connection electrode and the bank BB. The protective layer 118 may be a layer for protecting components disposed below the protective layer 118 and configured as a single layer or multilayer made of light transmissive epoxy, silicon oxide (SiOx), or silicon nitride (SiNx). However, the present disclosure is not limited thereto.

With reference to FIG. 3B, the second connection electrode CE2, which connects the driving transistor DT and the light-emitting element 120 disposed in each of the plurality of sub pixels SP, may be independently disposed in each of the plurality of sub pixels SP. Further, the first connection electrodes CE1, which are disposed in each of the plurality of sub pixels SP and connect the power line and the light-emitting element 120, may be connected to each other. That is, because a power voltage of the power line is applied in common to all the plurality of light-emitting elements 120 of the plurality of sub pixels SP, the single first connection electrode CE1 may be disposed on all the plurality of sub pixels SP.

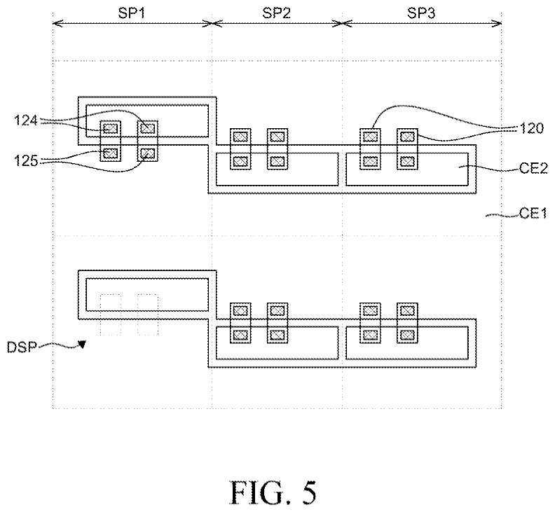

In exemplary aspects of the present specification, the display device 100 may be formed by transferring the plurality of light-emitting elements 120 onto the display panel PN formed with the bonding layer AD. However, in case that the light-emitting element 120 is lost from each of the plurality of sub pixels SP because of a transfer defect of the light-emitting element 120 or the light-emitting element 120 is transferred while deviating from an exact position, it is possible to perform a process of removing the defective light-emitting element 120 and forming the second planarization layer 116, the third planarization layer 117, the first connection electrode CE1, and the second connection electrode CE2 on the sub pixel. Therefore, the light-emitting element 120 may not be disposed on the sub pixel SP having a transfer defect. However, in the display device 100 according to exemplary aspects of the present specification, it is possible to repair a defective sub pixel DSP by transferring an additional light-emitting element 130 onto the defective sub pixel DSP on which the light-emitting element 120 is not disposed. This example configuration will be described with reference to FIGS. 5 to 7D.

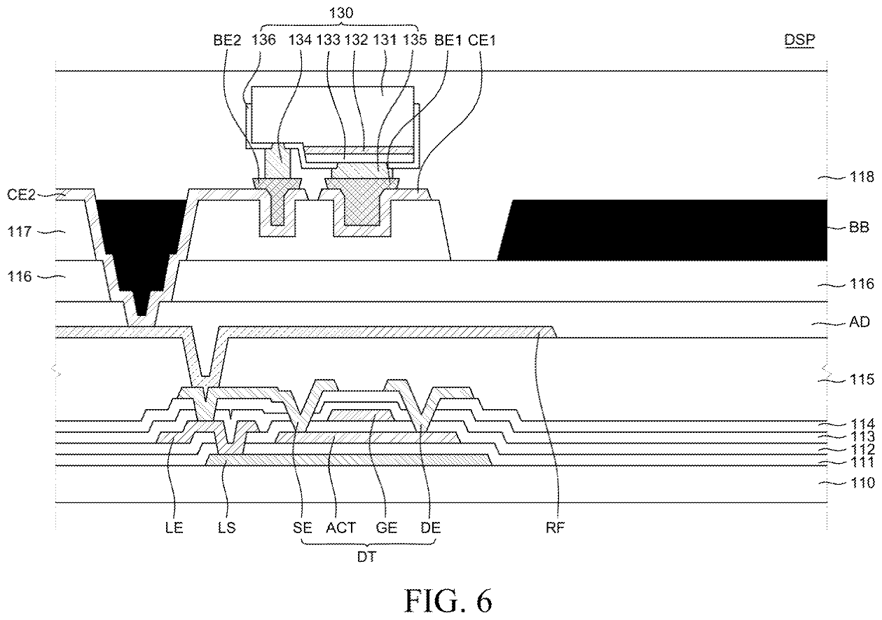

FIG. 5 is an enlarged top plan view of the display device according to the exemplary aspect of the present specification. FIG. 6 is a cross-sectional view of a defective sub pixel of the display device according to the exemplary aspect of the present specification. FIG. 5 is an enlarged top plan view illustrating a case in which one first sub pixel SP1, among the plurality of sub pixels SP, is a defective sub pixel DSP. FIG. 6 is a cross-sectional view illustrating a case in which a repair process is performed on the defective sub pixel DSP.

With reference to FIG. 5, in case that any one sub pixel SP, among the plurality of sub pixels SP, is the defective sub pixel DSP, the repair process may be performed on the defective sub pixel DSP. For example, the light-emitting element 120 is lost during the transfer process from one first sub pixel SP1 among the plurality of sub pixels SP, such that the light-emitting element 120 is not present, or the light-emitting element 120 is removed as the light-emitting element 120 is transferred while deviating from an exact position. Therefore, the first sub pixel SP1 may become the defective sub pixel DSP on which the light-emitting element 120 is not disposed.

Further, in the display device 100 according to the exemplary aspect of the present specification, the defective sub pixel DSP may be repaired by forming the first connection electrode CE1 and the second connection electrode CE2 on the entire display panel PN, additionally forming a first bonding electrode BE1 and a second bonding electrode BE2 only in the defective sub pixel DSP, and transferring the additional light-emitting element 130.

Specifically, with reference to FIG. 6, the first bonding electrode BE1 and the second bonding electrode BE2 are disposed on the first connection electrode CE1 and the second connection electrode CE2 in the defective sub pixel DSP. The first bonding electrode BE1 may be disposed on the first connection electrode CE1, and the second bonding electrode BE2 may be disposed on the second connection electrode CE2. The first bonding electrode BE1 may electrically connect the first connection electrode CE1 and a second additional electrode 135 of the additional light-emitting element 130, and the second bonding electrode BE2 may electrically connect the second connection electrode CE2 and a first additional electrode 134 of the additional light-emitting element 130. The first bonding electrode BE1 and the second bonding electrode BE2 may each be made of an electrically conductive material that has high reflectance and may bond the additional light-emitting element 130 onto the first connection electrode CE1 and the second connection electrode CE2. For example, the first bonding electrode BE1 and the second bonding electrode BE2 may be made of paste (Ag paste), indium, or the like.

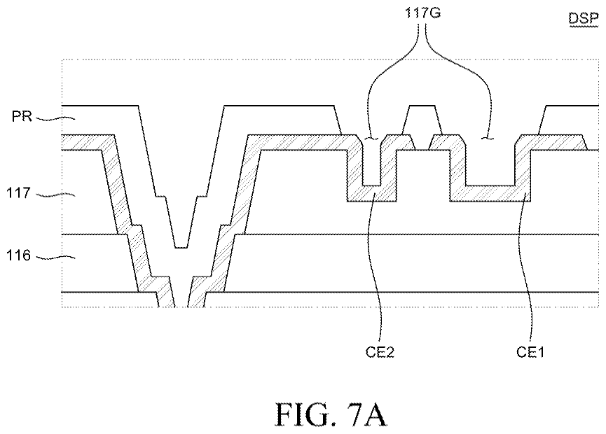

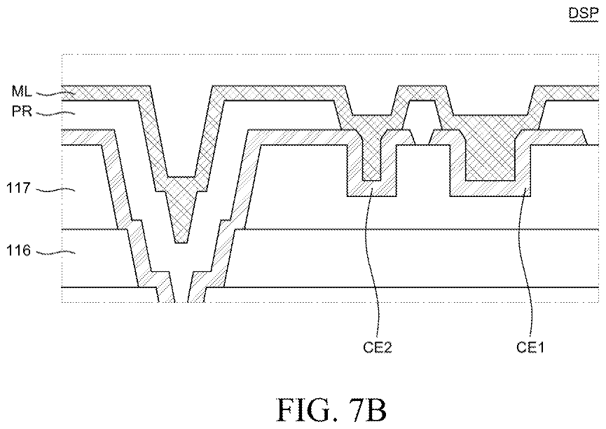

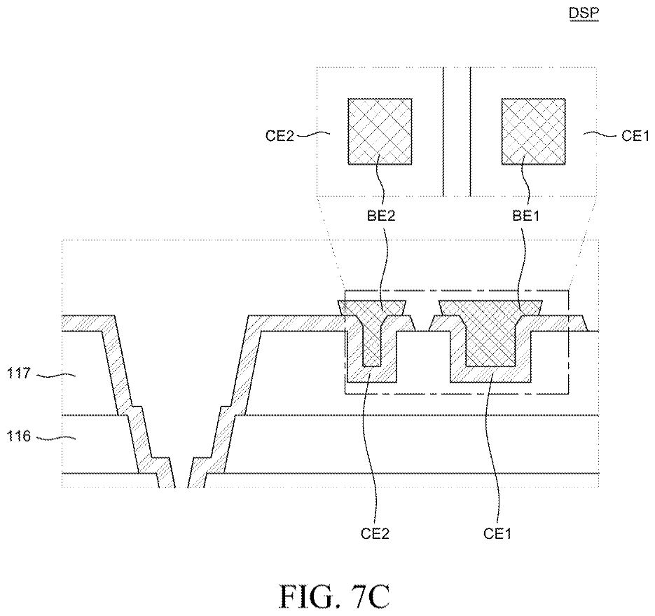

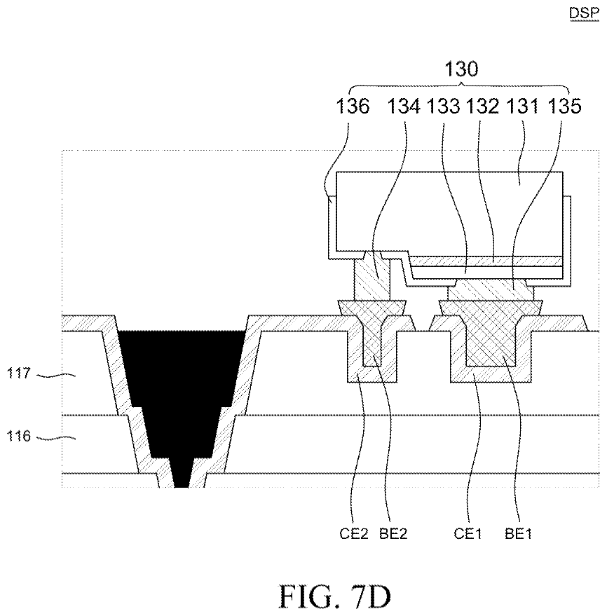

In some examples, an upper portion of the first bonding electrode BE1, which is disposed on an upper portion of the first connection electrode CE1, and an upper portion of the second bonding electrode BE2, which is disposed on an upper portion of the second connection electrode CE2, may each be formed to have an inversely tapered shape. The upper portions of the first and second bonding electrodes BE1 and BE2 may each be formed to have an inversely tapered shape by inclined surfaces of photoresist patterns PR formed on the first and second connection electrodes CET and CE2 at the time of forming the first bonding electrode BET and the second bonding electrode BE2. A detailed description will be made below with reference to FIGS. 7A to 7D.

The additional light-emitting element 130 is disposed on the first bonding electrode BET and the second bonding electrode BE2. The additional light-emitting element 130 includes a first additional semiconductor layer 131, an additional light-emitting layer 132, a second additional semiconductor layer 133, the first additional electrode 134, the second additional electrode 135, and an additional passivation layer 136.

The second additional semiconductor layer 133 is disposed on the first bonding electrode BET and the second bonding electrode BE2, and the first additional semiconductor layer 131 is disposed on the second additional semiconductor layer 133. The first additional semiconductor layer 131 may protrude to the outside of the second additional semiconductor layer 133, and a part of a bottom surface of the first additional semiconductor layer 131 may be exposed from the second additional semiconductor layer 133. The first additional semiconductor layer 131 and the second additional semiconductor layer 133 may each be a layer formed by doping a particular material with n-type and p-type impurities. For example, the first additional semiconductor layer 131 and the second additional semiconductor layer 133 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The additional light-emitting layer 132 is disposed between the first additional semiconductor layer 131 and the second additional semiconductor layer 133. The additional light-emitting layer 132 may emit light by receiving positive holes and electrons from the first additional semiconductor layer 131 and the second additional semiconductor layer 133. The additional light-emitting layer 132 may be configured as a single layer or a multi-quantum well (MQW) structure. For example, the additional light-emitting layer 132 may be made of indium gallium nitride (InGaN), gallium nitride (GaN), or the like. However, the present disclosure is not limited thereto.

The first additional electrode 134 is disposed on the bottom surface of the first additional semiconductor layer 131 exposed from the second additional semiconductor layer 133. The first additional electrode 134 may be disposed on a bottom surface of the first additional semiconductor layer 131 exposed from the additional light-emitting layer 132 and the second additional semiconductor layer 133. The first additional electrode 134 is an electrode that electrically connects the driving transistor and the first additional semiconductor layer 131. The first additional electrode 134 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second additional electrode 135 is disposed on a bottom surface of the second additional semiconductor layer 133. The second additional electrode 135 is an electrode that electrically connects the power line and the second additional semiconductor layer 133. The second additional electrode 135 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Therefore, the light-emitting element 120 is an LED chip having a horizontal (lateral) structure having an upper portion on which a pair of electrodes is disposed. In contrast, the additional light-emitting element 130 is an LED chip having a flip chip structure having a lower portion on which a pair of electrodes is disposed. Therefore, the light-emitting element 120 and the additional light-emitting element 130 may be configured as different types of light-emitting elements 120.

Next, the passivation layer 126 is disposed to surround the first additional semiconductor layer 131, the additional light-emitting layer 132, the second additional semiconductor layer 133, the first additional electrode 134, and the second additional electrode 135. The passivation layer 126 may be made of an insulating material and protect the first additional semiconductor layer 131, the additional light-emitting layer 132, and the second additional semiconductor layer 133. Further, a contact hole, through which the first additional electrode 134 and the second additional electrode 135 are exposed, may be formed in the additional passivation layer 136, such that the first bonding electrode BET, the second bonding electrode BE2, the first additional electrode 134, and the second additional electrode 135 may be electrically connected.

In some examples, a part of a side surface of the first additional semiconductor layer 131 may be exposed from the passivation layer 126. As described above, a part of the additional passivation layer 136 may be tom during a process of separating the light-emitting element 120, which is manufactured on a wafer, from the wafer. For example, a part of the additional passivation layer 136 adjacent to an upper edge of the first additional semiconductor layer 131 of the additional light-emitting element 130 may be torn during the process of separating the light-emitting element 120 from the wafer, such that a part of an upper portion of the side surface of the first additional semiconductor layer 131 may be exposed to the outside. However, the additional light-emitting element 130 is connected to the pixel circuit and the power line by a method of bonding the first additional electrode 134 and the second additional electrode 135 to the first and second bonding electrodes BE1 and BE2 disposed below the additional light-emitting element 130. Therefore, it is possible to minimize a short circuit defect caused by the first additional semiconductor layer 131 exposed from the additional passivation layer 136.

Lastly, the protective layer 118 may be formed on the additional light-emitting element 130 and protect the additional light-emitting element 130 from the outside.

In some examples, the first bonding electrode BE1 and the second bonding electrode BE2 are configured to fill a gap formed by the process of forming the contact hole in the third planarization layer 117 and connect the additional light-emitting element 130 to the first connection electrode CE1 and the second connection electrode CE2. Specifically, the contact hole of the third planarization layer 117 is also formed in the defective sub pixel DSP during the process of forming the contact hole in the third planarization layer 117 to expose the first electrode 124 and the second electrode 125 of the light-emitting element 120. Therefore, a groove of the third planarization layer 117 is formed in the defective sub pixel DSP during the process of forming the contact hole.

Further, after the contact hole and the groove are formed in the third planarization layer 117, a conductive layer is formed on the front surface of the substrate 110, and the first connection electrode CE1 and the second connection electrode CE2 may be formed by patterning the conductive layer. In the defective sub pixel DSP, the first connection electrode CE1 and the second connection electrode CE2 are formed along a shape of the groove of the third planarization layer 117, such that the first connection electrode CE1 and the second connection electrode CE2 may each be formed in a concave shape.

In examples where the additional light-emitting element 130 is disposed immediately on the first and second connection electrodes CE1 and CE2 each having the concave shape formed by the groove, a gap may be formed in a concave portion of each of the first and second connection electrodes CE1 and CE2. Because the first connection electrode CE1 and the second connection electrode CE2 are not formed to be flat, the first additional electrode 134 and the second additional electrode 135 of the additional light-emitting element 130 may not be properly connected to the first connection electrode CE1 and the second connection electrode CE2, and a gap, in which oxygen or moisture is present, may be formed in the groove, which may cause a defect in which various types of metal layers ML in the display panel PN are oxidized.

Therefore, in the display device 100 according to the exemplary aspect of the present specification, the gap may be removed by forming the first bonding electrode BE1 and the second bonding electrode BE2 that fill the concave portions of the first and second connection electrodes CE1 and CE2 formed by the groove of the third planarization layer 117. In addition, the additional light-emitting element 130 may be easily bonded and fixed onto the first and second bonding electrodes BE1 and BE2 each having a flat top surface and electrically connected to the first connection electrode CE1 and the second connection electrode CE2, thereby minimizing a turning on-off defect of the additional light-emitting element 130. In addition, the first bonding electrode BE1 and the second bonding electrode BE2 may each be made of an electrically conductive material having high reflectance and reflect the light, which is emitted from the additional light-emitting element 130, toward the upper portion of the display panel PN. Therefore, the first bonding electrode BE1 and the second bonding electrode BE2 may each serve as the reflective layer RF, thereby improving luminous efficiency of the display device 100.

Hereinafter, a method of manufacturing the display device 100 according to the exemplary aspect of the present specification will be described with reference to FIGS. 7A to 7D.

FIGS. 7A to 7D are process diagrams for explaining a method of manufacturing the display device according to the exemplary aspect of the present specification. FIGS. 7A to 7D are views for explaining a repair process of repairing the defective sub pixel DSP by forming the first bonding electrode BE1 and the second bonding electrode BE2 and transferring the additional light-emitting element 130 when the defective sub pixel DSP occurs.

With reference to FIG. 7A, when the transfer process of transferring the light-emitting element 120 onto the bonding layer AD is completed, the second planarization layer 116 and the third planarization layer 117 are formed in all the plurality of sub pixels SP including the defective sub pixel DSP. Further, the contact hole, through which the first electrode 124 and the second electrode 125 of the light-emitting element 120 are exposed, is formed in the third planarization layer 117, and the first connection electrode CE1 and the second connection electrode CE2 are formed on the third planarization layer 117. In this case, the light-emitting element 120 is not present in the defective sub pixel DSP, but a groove 117G may also be formed in the third planarization layer 117 during the process of forming the contact hole. Because it is difficult to manufacture a mask for forming the contact hole in consideration of a position of the defective sub pixel DSP, the contact holes may be formed in all the plurality of sub pixels SP including the defective sub pixel DSP. Further, the first connection electrode CE1 and the second connection electrode CE2 may also be formed on the groove 117G, i.e., the contact hole of the third planarization layer 117 of the defective sub pixel DSP.

Next, a photoresist layer is formed on the front surface of the substrate 110, and the photoresist pattern PR, which exposes the concave portions of the first and second connection electrodes CE1 and CE2 in the defective sub pixel DSP, is formed. Only the concave portions of the first and second connection electrodes CE1 and CE2 in the defective sub pixel DSP, i.e., only the groove 117G of the third planarization layer 117 may be exposed from the photoresist pattern PR. In this case, a side surface of the photoresist pattern PR disposed on the first connection electrode CE1 and the second connection electrode CE2 may be formed as an inclined surface.

With reference to FIG. 7B, the metal layer ML is formed on the photoresist pattern PR and disposed on the front surface of the substrate 110. The metal layer ML may be disposed to fill the concave portions of the first and second connection electrodes CE1 and CE2 on the groove 117G while covering the photoresist pattern PR. The metal layer ML may be made of a high-reflectance metallic material such as silver (Ag) or indium. For example, the metal layer ML may be formed by applying paste (Ag Paste) by means of a printing or inkjet coating method or formed by depositing indium.

Next, with reference to FIG. 7C, a process of stripping the photoresist pattern PR. A part of the metal layer ML, which covers the photoresist pattern PR, may also be removed during the process of removing the photoresist pattern PR. Therefore, only a part of the metal layer ML, which does not overlap the photoresist pattern PR, i.e., the concave portion of each of the first and second connection electrodes CE1 and CE2, i.e., the metal layer ML, which fills the groove 117G, remains on the substrate 110, such that the first bonding electrode BE1 and the second bonding electrode BE2 may be formed.

In this case, the metal layer ML may adjoin the side surface of the photoresist that is an inclined surface. Further, the photoresist pattern PR is removed, and the side surface of the metal layer ML, i.e., a side portion of each of the first and second bonding electrodes BE1 and BE2 is formed as an inclined surface, such that the upper portion of each of the first and second bonding electrodes BE1 and BE2 may be formed to have an inversely tapered shape.

Lastly, with reference to FIG. 7D, the additional light-emitting element 130 is transferred onto the first bonding electrode BE1 and the second bonding electrode BE2. The additional light-emitting element 130 may be fixed onto the first bonding electrode BE1 and the second bonding electrode BE2 by a method of applying pressure or heat. Therefore, the defective sub pixel DSP may be repaired by connecting the additional light-emitting element 130 to the first bonding electrode BE1 and the second bonding electrode BE2.

Therefore, in the example display device 100 and the method of manufacturing the display device 100 according to the exemplary aspect of the present specification, the first bonding electrode BE1 and the second bonding electrode BE2 are formed to fill the groove 117G of the third planarization layer 117 in the defective sub pixel DSP, thereby stably connecting the additional light-emitting element 130 to the pixel circuit. Because the first connection electrode CE1 and the second connection electrode CE2, which are formed on the groove 117G of the third planarization layer 117 in the defective sub pixel DSP, are formed concavely, it is difficult to ensure a contact area of the additional light-emitting element 130 with the first additional electrode 134 and the second additional electrode 135. However, because the first bonding electrode BE1 and the second bonding electrode BE2 are formed to fill the groove 117G, i. e., the concave portions of the first and second connection electrodes CE1 and CE2, the contact area with the first additional electrode 134 and the second additional electrode 135 may be increased, and the additional light-emitting element 130 may be stably and electrically connected to the first connection electrode CE1 and the second connection electrode CE2. In addition, the first bonding electrode BE1 and the second bonding electrode BE2 may be disposed to fill the inside of the groove 117G, thereby removing the gap formed in the groove 117G and protecting the components in the display panel PN from moisture and oxygen. Therefore, the first bonding electrode BE1 and the second bonding electrode BE2 are formed on the defective sub pixel DSP to fill the concave portions of the first and second connection electrodes CE1 and CE2, thereby easily repairing the defective sub pixel DSP and improving reliability of the repair process.

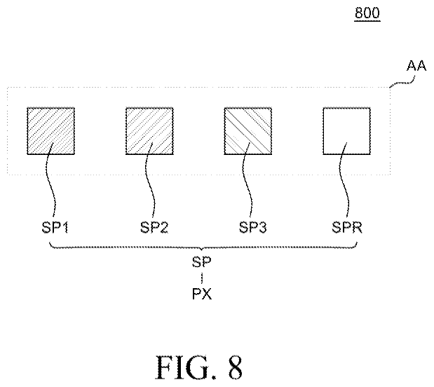

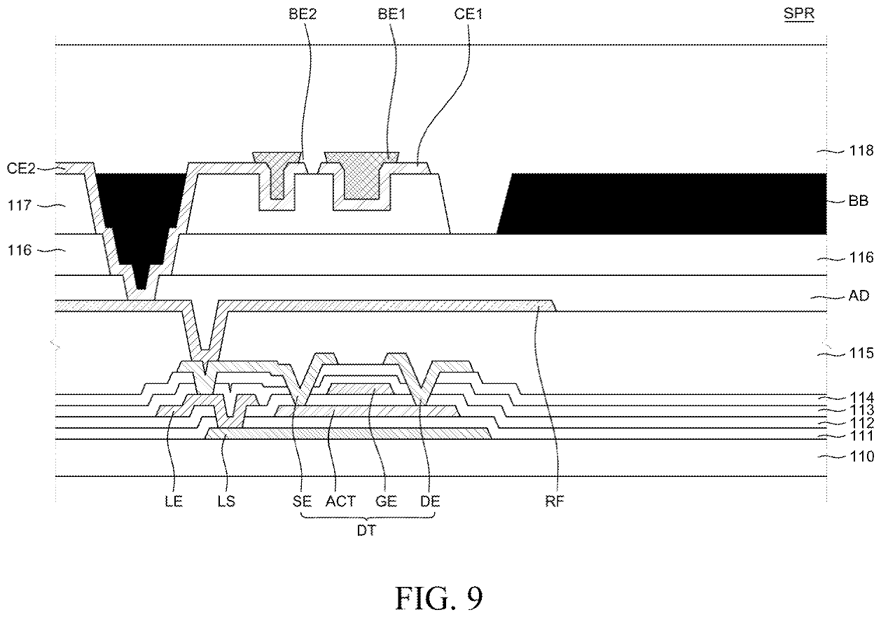

FIG. 8 is a schematic enlarged top plan view of a display device according to another exemplary aspect of the present specification. FIG. 9 is a cross-sectional view of a repair sub pixel of the display device according to another exemplary aspect of the present specification. A display device 800 illustrated in FIGS. 8 and 9 is substantially identical in configuration to the display device 100 illustrated in FIGS. 1 to 6, except for a configuration of the sub pixel SP. Therefore, repeated descriptions of the identical components will be omitted.

With reference to FIG. 8, the single pixel PX includes the plurality of sub pixels SP. Further, the plurality of sub pixels SP includes the first sub pixel SP1, the second sub pixel SP2, the third sub pixel SP3, and a repair sub pixel SPR. For example, a single pixel PX may include a single first sub pixel SP1, a single second sub pixel SP2, a single third sub pixel SP3, and a single repair sub pixel SPR.

In case that a transfer defect of the light-emitting element 120 occurs in any one of the first sub pixel SP1, the second sub pixel SP2, and the third sub pixel SP3, the defective sub pixel DSP may be repaired by using the repair sub pixel SPR. For example, in case that a dark spot defect occurs as the light-emitting element 120 is not transferred to any one of the first sub pixel SP1, the second sub pixel SP2, and the third sub pixel SP3 or the light-emitting element 120 is transferred while deviating from an exact position, the additional light-emitting element 130 is transferred to the repair sub pixel SPR during a subsequent process, such that the defective sub pixel DSP may be substituted with the repair sub pixel SPR.

With reference to FIG. 9, the first bonding electrode BE1 and the second bonding electrode BE2 may be disposed on the first connection electrode CE1 and the second connection electrode CE2 in the repair sub pixel SPR. In case that the light-emitting element 120 is normally transferred to all the first sub pixel SP1, the second sub pixel SP2, and the third sub pixel SP3, a separate additional light-emitting element 130 may not be disposed in the repair sub pixel SPR. Therefore, the protective layer 118 may be formed immediately on the first bonding electrode BE1 and the second bonding electrode BE2.

On the contrary, in case that a transfer defect occurs in any one of the first sub pixel SP1, the second sub pixel SP2, and the third sub pixel SP3, the additional light-emitting element 130 may be transferred onto the first bonding electrode BE1 and the second bonding electrode BE2 of the repair sub pixel SPR, and the repair sub pixel SPR may be operated instead of the defective sub pixel DSP.

Therefore, the display device 800 according to another exemplary aspect of the present specification may further include the separate repair sub pixel SPR that is substituted for the defective sub pixel DSP when the defective sub pixel DSP occurs. The light-emitting element 120 may not be transferred to the repair sub pixel SPR, and the second planarization layer 116, the third planarization layer 117, the first connection electrode CE1, the second connection electrode CE2, the first bonding electrode BE1, and the second bonding electrode BE2 may be formed on the bonding layer AD. Further, in case that a transfer defect of the light-emitting element 120 occurs in the first sub pixel SP1, the second sub pixel SP2, and the third sub pixel SP3, the additional light-emitting element 130 may be transferred onto the first bonding electrode BE1 and the second bonding electrode BE2 of the repair sub pixel SPR, and the repair sub pixel SPR may be operated instead of the defective sub pixel DSP.

Aspects of the present disclosure may also be described as follows:

Aspect 1. A display device comprising: a substrate on which a pixel including a plurality of sub pixels is disposed; a bonding layer on the substrate; a plurality of light-emitting elements in a first subset of the plurality of sub pixels and disposed on the bonding layer; a planarization layer on the bonding layer and the plurality of light-emitting elements; and an additional light-emitting element in a second subset of the plurality of sub pixels and disposed on the planarization layer.

Aspect 2. The display device of Aspect 1, wherein the plurality of light-emitting elements each comprises: a first semiconductor layer on the bonding layer; a second semiconductor layer on the first semiconductor layer; a light-emitting layer between the first semiconductor layer and the second semiconductor layer; a first electrode on the first semiconductor layer; and a second electrode on the second semiconductor layer.

Aspect 3. The display device of any of Aspects 1 to 2, wherein the additional light-emitting element comprises: a first additional semiconductor layer; a second additional semiconductor layer below the first additional semiconductor layer; an additional light-emitting layer between the first additional semiconductor layer and the second additional semiconductor layer; a first additional electrode disposed below the first additional semiconductor layer; and a second additional electrode disposed below the second additional semiconductor layer.

Aspect 4. The display device of any of Aspects 1 to 3, further comprising: a first connection electrode provided in each of the plurality of sub pixels and disposed on the planarization layer; and a second connection electrode provided in each of the plurality of sub pixels, disposed on the planarization layer, and spaced apart from the first connection electrode, wherein the first connection electrode is electrically connected to the first electrode and the first additional electrode, and wherein the second connection electrode is electrically connected to the second electrode and the second additional electrode.

Aspect 5. The display device of any of Aspects 1 to 4, wherein the planarization layer further comprises a groove that overlaps the first additional electrode and the second additional electrode in the sub pixel on which the additional light-emitting element is disposed among the plurality of sub pixels, and wherein the first connection electrode and the second connection electrode are formed in a concave shape along the groove.

Aspect 6. The display device of any of Aspects 1 to 5, further comprising: a first bonding electrode provided in the groove and disposed between the first connection electrode and the first additional electrode; and a second bonding electrode provided in the groove and disposed between the second connection electrode and the second additional electrode.

Aspect 7. The display device of any of Aspects 1 to 6, wherein an upper portion of the first bonding electrode and an upper portion of the second bonding electrode are disposed on an upper portion of the first connection electrode and an upper portion of the second connection electrode, and the upper portion of the first bonding electrode and the upper portion of the second bonding electrode each have an inversely tapered shape.

Aspect 8. The display device of any of Aspects 1 to 7, wherein the first connection electrode and the second connection electrode are each made of a transparent conductive material, and the first bonding electrode and the second bonding electrode are each made of an opaque conductive material.

Aspect 9. The display device of any of Aspects 1 to 8, wherein the plurality of light-emitting elements is disposed in the sub pixel different from the sub pixel on which the first bonding electrode and the second bonding electrode are disposed.

Aspect 10. The display device of any of Aspects 1 to 9, wherein the plurality of sub pixels comprises a plurality of first sub pixels, a plurality of second sub pixels, a plurality of third sub pixels, and one or more defective sub pixels, the first subset of the plurality of sub pixels in which the plurality of light-emitting elements is disposed includes the plurality of first sub pixels, the plurality of second sub pixels, and the plurality of third sub pixels, and the second subset of the plurality of sub pixels in which the additional light-emitting element is disposed includes the one or more defective sub pixels.

Aspect 11. The display device of any of Aspects 1 to 10, wherein the first bonding electrode and the second bonding electrode are disposed in the one or more defective sub pixels.

Aspect 12. The display device of any of Aspects 1 to 11, wherein the plurality of sub pixels comprises a plurality of first sub pixels, a plurality of second sub pixels, a plurality of third sub pixels, and a plurality of repair sub pixels, the first subset of the plurality of sub pixels in which the plurality of light-emitting elements is disposed includes the plurality of first sub pixels, the plurality of second sub pixels, and the plurality of third sub pixels, and the second subset of the plurality of sub pixels in which the additional light-emitting element is disposed includes one of the plurality of repair sub pixels.

Aspect 13. The display device of any of Aspects 1 to 12, wherein the first bonding electrode and the second bonding electrode are disposed in the plurality of repair sub pixels.

Aspect 14. The display device of any of Aspects 1 to 13, wherein the plurality of sub pixels comprises a plurality of first sub pixels, a plurality of second sub pixels, a plurality of third sub pixels, and a plurality of repair sub pixels, the plurality of light-emitting elements is formed in the plurality of first sub pixels, the plurality of second sub pixels, and the plurality of third sub pixels, and the additional light-emitting element is formed in one of the plurality of repair sub pixels.

Aspect 15. A display device comprising: a plurality of sub pixels formed on a substrate; a bonding layer on the substrate; a plurality of light-emitting elements formed on the bonding layer; a planarization layer on the bonding layer and the plurality of light-emitting elements; and at least one additional light-emitting element formed on the planarization layer.

Aspect 16. The display device of Aspect 15, wherein the plurality of light-emitting elements and the at least one additional light-emitting element are formed in different subsets of the plurality of sub pixels.

Aspect 17. The display device of any of Aspects 15 to 16, wherein the plurality of sub pixels comprises a plurality of first sub pixels, a plurality of second sub pixels, a plurality of third sub pixels, and one or more defective sub pixels, the plurality of light-emitting elements is formed in the plurality of first sub pixels, the plurality of second sub pixels, and the plurality of third sub pixels, and the additional light-emitting element is formed in the one or more defective sub pixels.

Aspect 18. The display device of any of Aspects 15 to 17, wherein the plurality of light-emitting elements each comprises: a first semiconductor layer on the bonding layer; a second semiconductor layer on the first semiconductor layer; a light-emitting layer between the first semiconductor layer and the second semiconductor layer; a first electrode on the first semiconductor layer; and a second electrode on the second semiconductor layer.

Aspect 19. The display device of any of Aspects 15 to 18, wherein the additional light-emitting element comprises: a first additional semiconductor layer; a second additional semiconductor layer below the first additional semiconductor layer; an additional light-emitting layer between the first additional semiconductor layer and the second additional semiconductor layer; a first additional electrode disposed below the first additional semiconductor layer; and a second additional electrode disposed below the second additional semiconductor layer.

Aspect 20. The display device of any of Aspects 15 to 19, further comprising: a bank layer formed of an opaque material on the planarization layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A display device comprising:
a substrate on which a pixel including a plurality of sub pixels is disposed;
a bonding layer on the substrate;
a plurality of light-emitting elements in a first subset of the plurality of sub pixels and disposed on the bonding layer;
a planarization layer on the bonding layer and the plurality of light-emitting elements; and
an additional light-emitting element in a second subset of the plurality of sub pixels and disposed on the planarization layer.

2. The display device of claim 1, wherein the plurality of light-emitting elements each comprises:
a first semiconductor layer on the bonding layer;
a second semiconductor layer on the first semiconductor layer;
a light-emitting layer between the first semiconductor layer and the second semiconductor layer;
a first electrode on the first semiconductor layer; and
a second electrode on the second semiconductor layer.

3. The display device of claim 2, wherein the additional light-emitting element comprises:
a first additional semiconductor layer;
a second additional semiconductor layer below the first additional semiconductor layer;
an additional light-emitting layer between the first additional semiconductor layer and the second additional semiconductor layer;
a first additional electrode disposed below the first additional semiconductor layer; and
a second additional electrode disposed below the second additional semiconductor layer.

4. The display device of claim 3, further comprising:
a first connection electrode provided in each of the plurality of sub pixels and disposed on the planarization layer; and
a second connection electrode provided in each of the plurality of sub pixels, disposed on the planarization layer, and spaced apart from the first connection electrode,
wherein the first connection electrode is electrically connected to the first electrode and the first additional electrode, and
wherein the second connection electrode is electrically connected to the second electrode and the second additional electrode.

5. The display device of claim 4, wherein the planarization layer further comprises a groove that overlaps the first additional electrode and the second additional electrode in the sub pixel on which the additional light-emitting element is disposed among the plurality of sub pixels, and
wherein the first connection electrode and the second connection electrode are formed in a concave shape along the groove.

6. The display device of claim 5, further comprising:
a first bonding electrode provided in the groove and disposed between the first connection electrode and the first additional electrode; and
a second bonding electrode provided in the groove and disposed between the second connection electrode and the second additional electrode.

7. The display device of claim 6, wherein an upper portion of the first bonding electrode and an upper portion of the second bonding electrode are disposed on an upper portion of the first connection electrode and an upper portion of the second connection electrode, and the upper portion of the first bonding electrode and the upper portion of the second bonding electrode each have an inversely tapered shape.

8. The display device of claim 6, wherein the first connection electrode and the second connection electrode are each made of a transparent conductive material, and the first bonding electrode and the second bonding electrode are each made of an opaque conductive material.

9. The display device of claim 6, wherein the plurality of light-emitting elements is disposed in the sub pixel different from the sub pixel on which the first bonding electrode and the second bonding electrode are disposed.

10. The display device of claim 6, wherein
the plurality of sub pixels comprises a plurality of first sub pixels, a plurality of second sub pixels, a plurality of third sub pixels, and one or more defective sub pixels,
the first subset of the plurality of sub pixels in which the plurality of light-emitting elements is disposed includes the plurality of first sub pixels, the plurality of second sub pixels, and the plurality of third sub pixels, and
the second subset of the plurality of sub pixels in which the additional light-emitting element is disposed includes the one or more defective sub pixels.

11. The display device of claim 10, wherein the first bonding electrode and the second bonding electrode are disposed in the one or more defective sub pixels.

12. The display device of claim 6, wherein
the plurality of sub pixels comprises a plurality of first sub pixels, a plurality of second sub pixels, a plurality of third sub pixels, and a plurality of repair sub pixels,
the first subset of the plurality of sub pixels in which the plurality of light-emitting elements is disposed includes the plurality of first sub pixels, the plurality of second sub pixels, and the plurality of third sub pixels, and
the second subset of the plurality of sub pixels in which the additional light-emitting element is disposed includes one of the plurality of repair sub pixels.

13. The display device of claim 12, wherein the first bonding electrode and the second bonding electrode are disposed in the plurality of repair sub pixels.

14. A display device comprising:
a plurality of sub pixels formed on a substrate;
a bonding layer on the substrate;
a plurality of light-emitting elements formed on the bonding layer;
a planarization layer on the bonding layer and the plurality of light-emitting elements; and
at least one additional light-emitting element formed on the planarization layer.

15. The display device of claim 14, wherein the plurality of light-emitting elements and the at least one additional light-emitting element are formed in different subsets of the plurality of sub pixels.

16. The display device of claim 14, wherein
the plurality of sub pixels comprises a plurality of first sub pixels, a plurality of second sub pixels, a plurality of third sub pixels, and one or more defective sub pixels,
the plurality of light-emitting elements is formed in the plurality of first sub pixels, the plurality of second sub pixels, and the plurality of third sub pixels, and
the additional light-emitting element is formed in the one or more defective sub pixels.

17. The display device of claim 6, wherein
the plurality of sub pixels comprises a plurality of first sub pixels, a plurality of second sub pixels, a plurality of third sub pixels, and a plurality of repair sub pixels,
the plurality of light-emitting elements is formed in the plurality of first sub pixels, the plurality of second sub pixels, and the plurality of third sub pixels, and
the additional light-emitting element is formed in one of the plurality of repair sub pixels.

18. The display device of claim 14, wherein the plurality of light-emitting elements each comprises:
a first semiconductor layer on the bonding layer;
a second semiconductor layer on the first semiconductor layer;
a light-emitting layer between the first semiconductor layer and the second semiconductor layer;
a first electrode on the first semiconductor layer; and
a second electrode on the second semiconductor layer.

19. The display device of claim 18, wherein the additional light-emitting element comprises:
a first additional semiconductor layer;
a second additional semiconductor layer below the first additional semiconductor layer;
an additional light-emitting layer between the first additional semiconductor layer and the second additional semiconductor layer;
a first additional electrode disposed below the first additional semiconductor layer; and
a second additional electrode disposed below the second additional semiconductor layer.

20. The display device of claim 14, further comprising:
a bank layer formed of an opaque material on the planarization layer.
